(19) United States
(12) Patent Application Publication
(10) Pub. No.: US 2002/0173141 A1
(43) Pub. Date: Nov. 21, 2002

(54) Method for fabricating contact holes in DRAM circuits

(75) Inventor: Horng-Huei Tseng, Hsinchu (TW)

Correspondence Address: DOUGHERTY & TROXELL, SUITE 1404, 5205 LEESBURG PIKE, FALLS CHURCH, VA, 22041, US

(73) Assignee: Vanguard International Semiconductor Corporation

(21) Appl. No.: 09/859,433

(22) Filed: May 18, 2001

(51) Int. Cl. H01L 21/4763; H01L 21/8242; H01L 21/44

(52) U.S. Cl. 438/637; 438/241; 438/672

(57) ABSTRACT

The present invention provides a method for fabricating contact holes in DRAM circuits, comprising the steps of: providing a semiconductor substrate and forming a gate dielectric layer, a gate material layer and a first dielectric layer; patterning the gate dielectric layer, the gate material layer and the first dielectric layer, so as to form a gate structure on an active region and an interconnection structure on a field oxide region; depositing a second dielectric layer and etching the second dielectric layer so as to form spacers on the gate structure and the interconnection structure; forming source/drain regions on the semiconductor substrate; depositing and patterning a first photoresist layer so as to expose the surface of the first dielectric layer of the interconnection structure; etching the first dielectric layer of the interconnection structure until the gate material layer of the interconnection structure is exposed; removing the first photoresist pattern; depositing a third dielectric layer composed of a different material from the first and the second dielectric layers; depositing and patterning a second photoresist layer on the third dielectric layer; etching the third dielectric layer, so as to form a first contact hole opening and a second contact hole opening, wherein the first contact hole opening exposes the source/drain region on the active region and the second contact hole opening exposes the gate material layer on the interconnection structure; and filling the contact hole openings with a conductor material. In this manner, self-aligned contact holes are completed.

### BACKGROUND OF THE INVENTION

1. Field of the Invention

The present invention generally relates to a method for fabricating contact holes in DRAM circuits, and more particular, to a method for fabricating self-aligned contact holes so as to eliminate the problems due to etching and to further improve the fabrication yield when the contacts for the gate structure and the interconnection structure are formed.

2. Description of the Prior Art

In the semiconductor industry, the dynamic random access memory (DRAM) has become a milestone integrated circuit (IC) device for use, for example, in data storage such as the memory device in computers. In general, a DRAM is mainly constructed by a field-effect transistor (FET) and a capacitor. The capacitor is used for storing a certain amount of charges so as to determine the 0/1 access during the memory operation. The source of the FET is connected to the storage node of the capacitor. The charge signal is stored in the capacitor and accessed through the transistor. The storage capacitor comprises a contact and is connected to the first source/drain region of the FET. The capacitor stores the binary data (0's and 1's) in terms of charges. The second source/drain region of the FET is connected to the word line and performs read/write operations through the peripheral circuit of the DRAM. The word line is constructed by the gate of the FET and used for random accesses of the DRAMs.

In the prior art, a DRAM is formed by a self-aligned contact hole process, in which the contact holes for the gate structure and the interconnection structure are formed. Please refer to FIG. 1 to FIG. 1C, which are schematic diagrams illustrating the steps of a method for fabricating contact holes in DRAM circuits in the prior art. As shown in FIG. 1A, a field oxide region 15 is formed on a semiconductor substrate 10. Then a gate structure 1 is formed on an active region and an interconnection structure 2 is formed on the field oxide region 15. The gate structure 1 comprises a dielectric layer 25, spacers 30, a gate material layer 35 and a gate dielectric layer 45 between the source/drain regions 30. The interconnection structure 2 comprises a dielectric layer 60, spacers 50, a gate material layer 55 and a gate dielectric layer 65. Finally, a silicon dioxide layer 20 is deposited on the substrate 10.

Then, as shown in FIG. 1B, a photoresist layer 70 is deposited and patterned so as to provide two openings. The photoresist pattern serves as a mask for use in etching the silicon dioxide layer 20 so as to form a first opening 80 exposing a source/drain region 40 on the active region and a second opening 90 exposing the dielectric layer 60 of the interconnection structure 2, as shown in FIG. 1C. Finally, the openings 80 and 90 are filled with a conductor material such as poly-silicon, silicide and metal, so as to complete the contact holes for the DRAM.

However, in the prior art, since the dielectric layer 60 is composed of silicon nitride, the etching step for removing the silicon dioxide layer 20 stops at the dielectric layer 60 of the interconnection structure 2. As a result, the region desired to be exposed cannot be exposed. If the etching process continues, the source/drain region 40 on the active region will be over-etched, adversely affecting the yield.

Therefore, the present invention discloses a method for fabricating contact holes in DRAM circuits. In this method, self-aligned contact holes are fabricated so as to eliminate the problems due to etching and to further improve the fabrication yield when the contacts for the gate structure and the interconnection structure are formed.

### SUMMARY OF THE INVENTION

It is the primary object of the present invention to provide a method for fabricating contact holes in DRAM circuits, wherein the problems due to etching are considerably eliminated and the fabrication yield is improved when the contacts for the gate structure and the interconnection structure are formed.

It is another object of the present invention to provide a method for fabricating self-aligned contact holes that remains the source/drain region undamaged.

In order to achieve the foregoing objects, the present invention provides a method for fabricating contact holes in DRAM circuits, comprising the steps of: providing a semiconductor substrate and forming a gate dielectric layer, a gate material layer and a first dielectric layer; patterning the gate dielectric layer, the gate material layer and the first dielectric layer, so as to form a gate structure on an active region and an interconnection structure on a field oxide region; depositing a second dielectric layer and etching the second dielectric layer so as to form spacers on the gate structure and the interconnection structure; forming source/drain regions on the substrate; depositing and patterning a first photoresist layer so as to expose the surface of the first dielectric layer of the interconnection structure; etching the first dielectric layer of the interconnection structure until the gate material layer of the interconnection structure is exposed; removing the first photoresist pattern; depositing a third dielectric layer composed of a different material from the first and the second dielectric layers; depositing and patterning a second photoresist layer on the third dielectric layer; etching the third dielectric layer, so as to form a first contact hole opening and a second contact hole opening, wherein the first contact hole opening exposes the source/drain region on the active region and the second contact hole opening exposes the gate material layer on the interconnection structure; and filling the contact hole openings with a conductor material.

The major difference from the prior art is that a third dielectric layer (composed of a different material from that of the first and the second dielectric layers) is used for performing two etching steps so as to expose the contact hole opening of the source/drain region on the active region and the contact hole opening of the gate material on the interconnection structure and further complete the contact holes in the DRAM. In this manner, the problems due to the unexposed gate material layer by incompletely etching and the damaged source/drain region by over-etching can be eliminated. Therefore, the present invention can improve the yield and reduce the fabrication cost.

### BRIEF DESCRIPTION OF THE DRAWINGS

The objects, spirits and advantages of the preferred embodiments of the present invention will be readily understood by the accompanying drawings and detailed descriptions, wherein:

FIG. 1A to FIG. 1C are schematic diagrams illustrating the steps of a method for fabricating contact holes in DRAM circuits in the prior art;

FIG. 2A is a schematic diagram illustrating the step of forming a gate structure and an interconnection structure on a semiconductor substrate in accordance with the preferred embodiment of the present invention;

FIG. 2B is a schematic diagram illustrating the step of forming spacers and source/drain regions in accordance with the preferred embodiment of the present invention;

FIG. 2C is a schematic diagram illustrating the step of depositing and patterning a first photoresist layer in accordance with the preferred embodiment of the present invention;

FIG. 2D is a schematic diagram illustrating the step of etching the first dielectric layer of the interconnection structure in accordance with the preferred embodiment of the present invention;

FIG. 2E is a schematic diagram illustrating the step of removing the first photoresist layer in accordance with the preferred embodiment of the present invention;

FIG. 2F is a schematic diagram illustrating the step of depositing a third dielectric layer and forming a second photoresist layer in accordance with the preferred embodiment of the present invention;

FIG. 2G is a schematic diagram illustrating the step of etching the first dielectric layer of the interconnection structure and forming a first contact hole opening and a second contact hole opening in accordance with the preferred embodiment of the present invention; and

FIG. 2H is a schematic diagram illustrating the step of filling the contact hole openings with a conductor material in accordance with the preferred embodiment of the present invention.

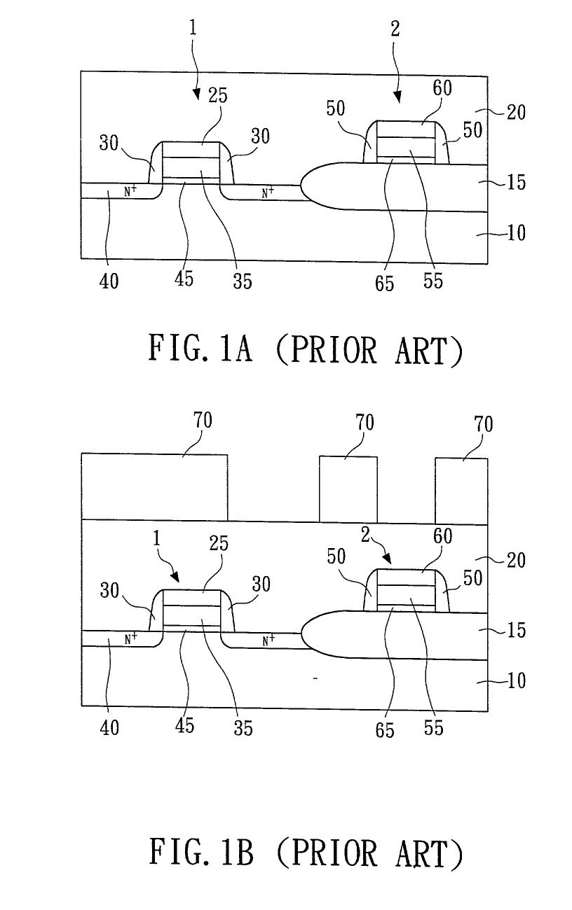

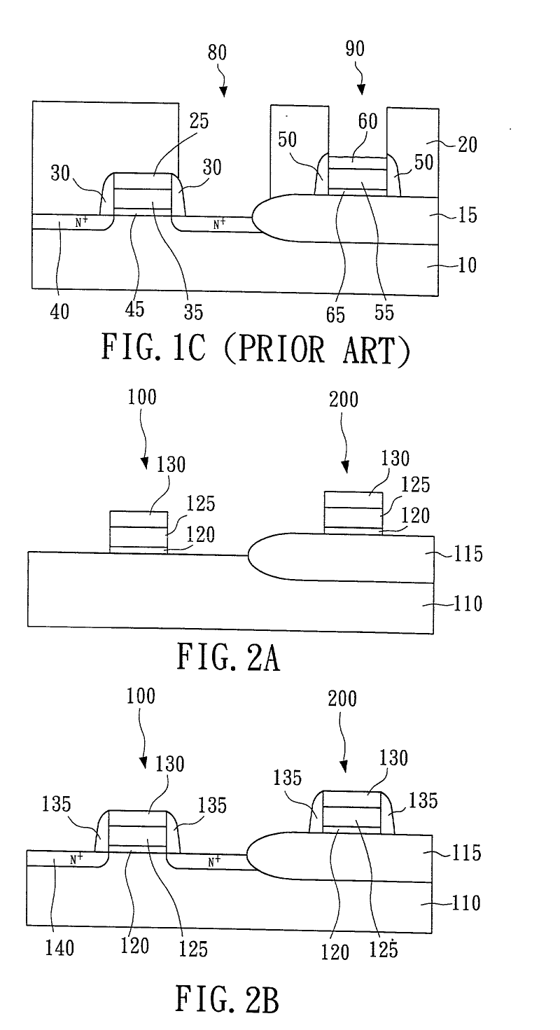

### DETAILED DESCRIPTION OF THE INVENTION

The present invention is described with reference to a preferred embodiment wherein self-aligned contact holes in DRAM circuits are formed on a p-type substrate.

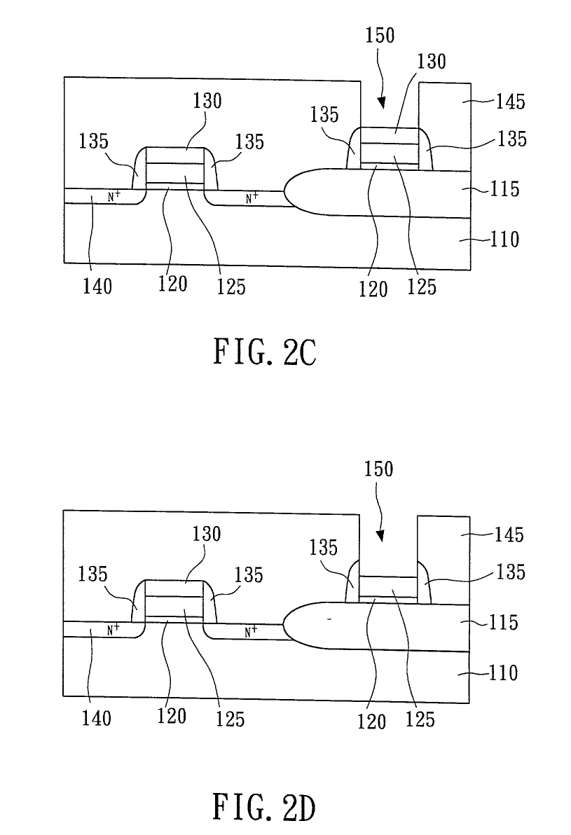

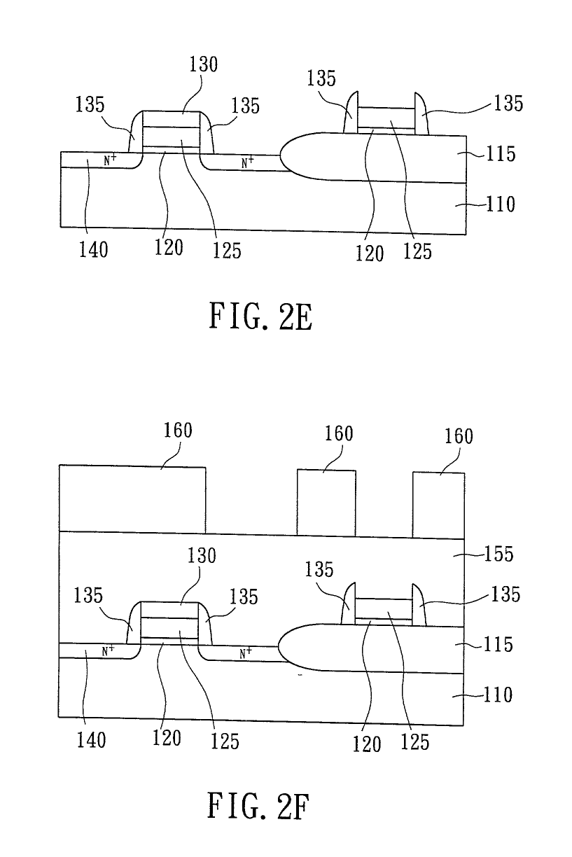

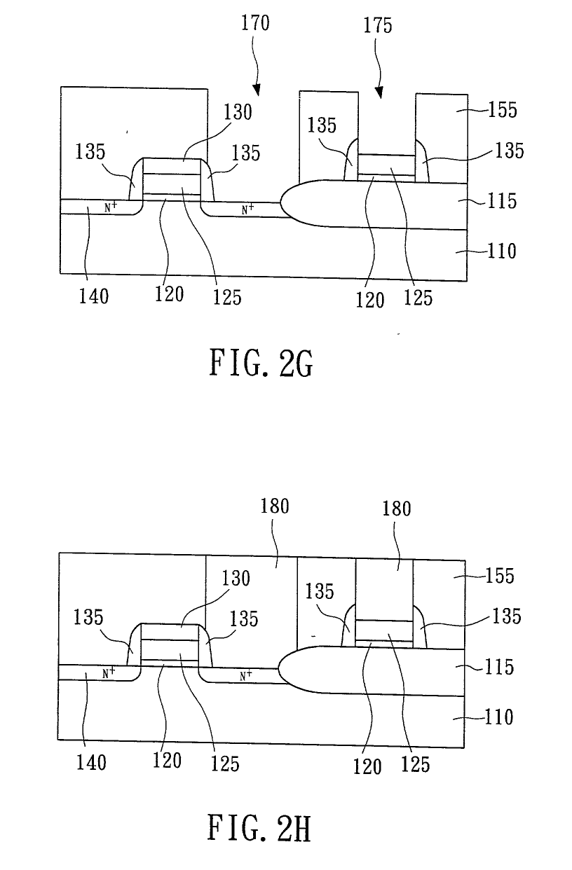

Please refer to FIG. 2A, wherein there is provided a p-type semiconductor substrate 110. On the p-type semiconductor substrate 110, a field oxide layer 115 for isolation is formed by conventional methods such as chemical vapor-phase deposition (CVD). Then, a gate dielectric layer 120, a gate material layer 125 and a first dielectric layer 130 are formed and patterned so as to define a gate structure 100 on an active region and an interconnection structure 200 on a field oxide region. The gate dielectric layer 120 can be composed of silicon dioxide. The gate material layer 125 can be composed of poly-silicon or silicide. The first dielectric layer 130 can be composed of silicon nitride.

Then, a second dielectric layer is deposited and back-etched so as to form spacers 135 on the gate structure 100 and the interconnection structure 200. The second dielectric layer can be composed of silicon nitride. Doping is performed by using the gate structure 100 and the interconnection structure 200 as a mask. The n-type dopant can be solid-state As, solid-state P or gaseous AsH₃. As a result, source/drain regions 140 are formed on the semiconductor substrate 110, as shown in FIG. 2B.

The present invention is particularly characterized in that a first photoresist layer 145 is deposited and patterned to provide an opening 150 so as to expose the surface of the first dielectric layer 130 of the interconnection structure 200, as shown in FIG. 2C.

Later, as shown in FIG. 2D, the first dielectric layer 130 of the interconnection structure 200 is etched by using the photoresist pattern 145 as a mask and the gate material layer 125 as an etching stop layer until the gate material layer 125 of the interconnection structure 200 is exposed. Meanwhile, the etching solution can be the same as that of silicon nitride (i.e. the material that the gate material layer 125 is made of).

Then, the first photoresist pattern 145 is removed, as shown in FIG. 2E.

A third dielectric layer 155 is deposited. A second photoresist layer 160 is deposited and patterned on the third dielectric layer 155. The third dielectric layer can be composed of a silicon dioxide layer, which is different from the first and the second dielectric layers (both made of silicon nitride). The second photoresist pattern 160 provides two openings serving as etching windows for the coming etching steps, as shown in FIG. 2F.

The third dielectric layer 155 is etched by using the second photoresist pattern 160 as a mask so as to form a first opening 170 and a second opening 175. This step is performed by using dry etching. For the first opening 170, the third dielectric layer 155 is etched until the source/drain region 140 on the active region; for the second opening 175, the third dielectric layer 155 is etched until the gate material layer 125 on the interconnection structure. Therefore, the first opening 170 is a contact hole opening for exposing the source/drain region 140 on the active region, and the second opening 175 is a contact hole opening for exposing the gate material layer 125 on the interconnection structure, as shown in FIG. 2G.

Finally, please refer to FIG. 2H, in which the first and second contact hole openings 170 and 175 are filled with a conductor material 180, and then planarized by chemical mechanical polishing (CMP) so as to remove the residual conductor material outside the first opening 170 and the second opening 175. The conductor material can be poly-silicon, silicide or metal. In this manner, self-aligned contact holes are completed.

In conclusion, the present invention is different from the prior art in that a third dielectric layer (composed of a different material from that of the first and the second dielectric layers) is used for performing two etching steps so as to expose the contact hole opening of the source/drain region on the active region and the contact hole opening of the gate material on the interconnection structure and further complete the contact holes in the DRAM. In this manner, the problems due to the unexposed gate material layer by incompletely etching and the damaged source/drain region by over-etching can be eliminated. Therefore, the present invention can improve the yield and reduce the fabrication cost.

As discussed so far, in accordance with the present invention, there is provided a method for fabricating contact holes in DRAM circuits, in which self-aligned contact holes are fabricated so as to eliminate the problems due to etching and to further improve the fabrication yield when the contacts for the gate structure and the interconnection structure are formed. Consequently, the present invention has been examined to be progressive and has great potential in commercial applications.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is

1. A method for fabricating contact holes in DRAM circuits, comprising the steps of:
(a) providing a semiconductor substrate and forming a gate dielectric layer, a gate material layer and a first dielectric layer;
(b) patterning said gate dielectric layer, said gate material layer and said first dielectric layer, so as to form a gate structure on an active region and an interconnection structure on a field oxide region;
(c) depositing a second dielectric layer and etching said second dielectric layer so as to form spacers on said gate structure and said interconnection structure;
(d) forming source/drain regions on said semiconductor substrate;
(e) depositing and patterning a first photoresist layer so as to expose the surface of said first dielectric layer of said interconnection structure;
(f) etching said first dielectric layer of said interconnection structure until said gate material layer of said interconnection structure is exposed;
(g) removing said first photoresist pattern;
(h) depositing a third dielectric layer composed of a different material from said first and said second dielectric layers;
(i) depositing and patterning a second photoresist layer on said third dielectric layer; and
(j) etching said third dielectric layer, so as to form a first contact hole opening and a second contact hole opening, wherein said first contact hole opening exposes said source/drain region on said active region and said second contact hole opening exposes said gate material layer on said interconnection structure.

2. The method for fabricating contact holes in DRAM circuits according to claim 1, further comprising, after said step (j), a step (k) of filling said contact hole openings with a conductor material.

3. The method for fabricating contact holes in DRAM circuits according to claim 2, wherein said conductor material is one of poly-silicon, metal-silicide, α-silicon, and metal.

4. The method for fabricating contact holes in DRAM circuits according to claim 1, wherein said gate dielectric layer is a silicon dioxide layer.

5. The method for fabricating contact holes in DRAM circuits according to claim 1, wherein said gate material layer is one of poly-silicon, metal-silicide, α-silicon, and metal.

6. The method for fabricating contact holes in DRAM circuits according to claim 1, wherein said first dielectric layer is a silicon nitride layer.

7. The method for fabricating contact holes in DRAM circuits according to claim 1, wherein said second dielectric layer is a silicon nitride layer.

8. The method for fabricating contact holes in DRAM circuits according to claim 1, wherein said third dielectric layer is a silicon dioxide layer.

9. The method for fabricating contact holes in DRAM circuits according to claim 1, wherein said first photoresist pattern is composed of positive photoresist.

10. The method for fabricating contact holes in DRAM circuits according to claim 1, wherein said second photoresist pattern is composed of positive photoresist.

11. A method for fabricating self-aligned contact holes, comprising the steps of:
(a) providing a semiconductor substrate and forming a gate dielectric layer, a gate material layer and a first dielectric layer;
(b) patterning said gate dielectric layer, said gate material layer and said first dielectric layer, so as to form a gate structure on a first region on said semiconductor substrate and an interconnection structure on a second region on said semiconductor substrate;
(c) depositing a second dielectric layer and etching said second dielectric layer so as to form spacers on said gate structure and said interconnection interconnection structure;
(d) forming source/drain regions on said semiconductor substrate;
(e) depositing and patterning a first photoresist layer so as to expose the surface of said first dielectric layer of said interconnection structure;
(f) etching said first dielectric layer of said interconnection structure until said gate material layer of said interconnection structure is exposed;
(g) removing said first photoresist pattern;
(h) depositing a third dielectric layer composed of a different material from said first and said second dielectric layers;
(i) depositing and patterning a second photoresist layer on said third dielectric layer; and
(j) etching said third dielectric layer, so as to form a first contact hole opening and a second contact hole opening, wherein said first contact hole opening exposes said source/drain region on said first region and said second contact hole opening exposes said gate material layer on said interconnection structure.

12. The method for fabricating self-aligned contact holes according to claim 11, further comprising, after said step (j), a step (k) of filling said contact hole openings with a conductor material.

13. The method for fabricating self-aligned contact holes according to claim 12, wherein said conductor material is one of poly-silicon, silicide, α-silicon, and metal.

14. The method for fabricating self-aligned contact holes according to claim 11, wherein said gate dielectric layer is a silicon dioxide layer.

15. The method for fabricating self-aligned contact holes according to claim 11, wherein said gate material layer is one of poly-silicon and silicide.

16. The method for fabricating self-aligned contact holes according to claim 11, wherein said first dielectric layer is a silicon nitride layer.

17. The method for fabricating self-aligned contact holes according to claim 11, wherein said second dielectric layer is a silicon nitride layer.

18. The method for fabricating self-aligned contact holes according to claim 11, wherein said third dielectric layer is a silicon dioxide layer.

19. The method for fabricating self-aligned contact holes according to claim 11, wherein said first photoresist pattern is composed of positive photoresist.

20. The method for fabricating self-aligned contact holes according to claim 11, wherein said second photoresist pattern is composed of positive photoresist.
